(19) United States
(12) Patent Application Publication
(10) Pub. No.: US 2026/0317950 A1
(43) Pub. Date: Oct. 15, 2026

(54) STRONGLY INTERACTING, TWO-DIMENSIONAL, DIPOLAR SPIN ENSEMBLE IN (111)-ORIENTED DIAMOND FOR QUANTUM SENSING AND SIMULATION

(71) Applicant: The Regents of the University of California, Oakland, CA (US)

(72) Inventors: Lillian Hughes, Santa Barbara, CA (US); Ania C. Jayich, Santa Barbara, CA (US); Simon Meynell, Burnaby (CA); Norman Yao, Belmont, MA (US); Kunal Mukherjee, Palo Alto, CA (US); Weijie Wu, Cambridge, MA (US); Emily J. Davis, New York, NY (US)

(73) Assignee: The Regents of the University of California, Oakland, CA (US)

(21) Appl. No.: 19/647,295

(22) Filed: Apr. 14, 2026

Related U.S. Application Data
(60) Provisional application No. 63/788,651, filed on Apr. 14, 2025.

(51) Int. Cl. C30B 29/04; C01B 32/28; C30B 25/10; C30B 31/06; G01R 33/26

(52) U.S. Cl. CPC C30B 29/04; C01B 32/28; C30B 25/105; C30B 31/06; G01R 33/26

(57) ABSTRACT

A composition of matter including a diamond layer having a (111) orientation or miscut thereof, wherein the diamond layer comprises a doped layer comprising a two dimensional ensemble of nitrogen vacancy centers characterized by (1) a spacing of nearest neighbor ones of the centers in a two dimensional plane of the doped layer being larger than a thickness of the doped layer; and (2) spins of the centers generating a non-zero dipolar induced mean field distribution.

### CROSS REFERENCE TO RELATED APPLICATIONS

This application claims the benefit under 35 U.S.C. Section 119 (e) of co-pending and commonly-assigned U.S. provisional patent application Ser. No. 63/788,651 filed on Apr. 14, 2025, by Lillian Hughes; Ania C. Jayich; Simon Meynell; Norman Yao; Kunal Mukherjee; Weijie Wu; Emily J. Davis, entitled “A STRONGLY INTERACTING, TWO-DIMENSIONAL, DIPOLAR SPIN ENSEMBLE IN (111)-ORIENTED DIAMOND FOR QUANTUM SENSING AND SIMULATION,” Attorney Docket 30794.874USP1 (UC Ref. 2025-368-1), which application is incorporated by reference herein.

### STATEMENT REGARDING FEDERALLY SPONSORED RESEARCH AND DEVELOPMENT

This invention was made with government support under DE-SC0019241 awarded by the U.S. Department of Energy, W911NF-20-1-0136 awarded by the Army Research Laboratory-Army Research Office, and 1906325 awarded by the National Science Foundation. The government has certain rights in the invention.

### BACKGROUND OF THE INVENTION

### Field of the Invention

The present disclosure relates to systems and methods for forming two dimensional spin ensembles with non-zero average dipolar interactions useful for sensing and quantum simulation applications.

### Description of the Related Art

Diamond is at the forefront of solid-state quantum technologies and spin ensembles in diamond with strong dipolar interactions and controlled dimensionality have become an important platform for quantum sensing and simulation. However, the tantalizing promise of these systems for 1) entanglement-enhanced metrology, leading to sensitivities beyond the standard quantum limit, and 2) simulation of equilibrium phase diagrams and non-equilibrium dynamics of positionally-disordered dipoles has been hampered by outstanding challenges in the controlled synthesis of dense, two dimensional spin ensembles with non-zero average dipolar interactions and with coherence limited by dipolar interactions amongst the spin ensemble itself. The present disclosure satisfies this need.

### SUMMARY OF THE INVENTION

The present disclosure demonstrates the synthesis and characterization of dense nitrogen and nitrogen-vacancy (NV) center ensembles with control over dimensionality and dipolar interactions. The methods and devices described herein create 2D strongly interacting dipolar ensembles in (111)-oriented diamond that provide unique advantages for quantum technologies which cannot be achieved with 3D ensembles or (001)-oriented diamond. Embodiments described herein will impact a wide audience, providing foundational developments in diamond materials synthesis and characterization for applications including, but not limited to, quantum sensing and simulation.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIG. 1 is a flowchart illustrating a method of making a composition of matter.

FIGS. 2A-2F illustrate creation of dense, 2D, (111) NV ensembles. FIG. 2A is a schematic illustrating a preferentially aligned (111) 2D NV ensemble with strong NV-NV interactions. FIG. 2B shows secondary ion mass spectrometry (SIMS) depth profile showing higher nitrogen concentration in a (111) delta-doped diamond (red, solid-later referred to as sample C) as compared to an (001) sample (blue, dashed). Both substrates have similar miscut angles of (~1.6°) and were grown with similar doping conditions: 10 minute doping time and a gas ratio of [¹⁵N₂]/[¹²CH₄]=12.5. FIG. 2C shows Rabi measurement on a (111) 2D NV ensemble (later referred to as sample A) showing high contrast indicative of the preferential alignment. FIG. 2D shows PL scan of sample A. The dashed line shows a linecut over which ODMR is performed in the presence of a ~32 Gauss field. FIG. 2E shows The ODMR data show preferential alignment of the grown-in NV centers along the (111) direction, with no other NV orientations visible at any point in the diamond epilayer. FIG. 2F shows simulated dipolar interaction-induced mean field distribution for polarized, 17 nm thick (001) (blue) and (111) (red) NV ensembles with a single-group density of 2 ppm·nm, illustrating an asymmetric distribution for (111) due to the uniformly positive dipolar interaction energy.

FIGS. 3A-3D. (111) illustrate PECVD growth, surface morphology, and deltadoped nitrogen incorporation. FIG. 3A shows diamond growth rate versus substrate miscut angle. Blue circles show (111) samples grown with 0.1% CH₄, orange triangles show (111) with 0.05% CH₄, and yellow shows (001) with 0.1% CH₄. Error bars are estimated from the ¹³C SIMS step function used to calculate the growth rate of the epitaxial layer. Trend lines are the result of a weighted linear regression and include the standard error. FIG. 3B shows AFM showing growth morphology with various polar miscut angles (θ), epilayer thickness (tₑ), methane content in the growth plasma, and resulting rms roughness (S_{q}). The azimuthal miscut direction is indicated by inset arrows. The highest and lowest miscut samples were grown simultaneously and are later referenced in this work as samples A and B, respectively. FIG. 3C is a plot of SIMS measured nitrogen concentration (normalized by doping time t_{d}) versus gas flow ratios showing increasing incorporation with higher nitrogen content in the growth plasma. Data points represent an average of N diamond samples, and error bars show the standard error of the mean. Our highest measured 2D density [sample C, 1.9 (0.2)×10⁴ ppmnm] was grown with a [¹⁵N₂]/[¹²CH₄] ratio of 12 and doping time of 10 min. FIG. 3D is a SIMS profile of a sample grown with three different doping times, as indicated on the plot. The data show thin layer confinement (FWHM≈4 nm for each peak) and slight increased density with longer doping time.

FIGS. 4A-4C illustrate miscut as a tuning knob for NV incorporation during growth. FIG. 4A shows ss-grown scanning confocal PL images taken under 80-μW excitation for samples A and B grown simultaneously with different miscuts of 3.0° and 0.96°, respectively. The color scale is the same for the two images, showing increased NV fluorescence in sample A (higher miscut). FIG. 4B is a Plot of NV density in samples A (circles) and B (triangles) during different stages of processing. The dashed line highlights different stages in the processing timeline from as-grown with no annealing or irradiation (black data), to annealed after growth (blue data), to postelectron irradiation and subsequent annealing (red data). The as-grown density of sample Aρ_{NV}=4.5±0.5 ppmnm was measured at three different locations on the sample with the decoherence-based method (the saturated coherence of the NV ensemble under an XY8 sequence) and calibrated to an optical measurement of ΔPL, a proxy for NV density that represents the intensity difference between the mₛ=0 and ±1 states in a Rabi experiment as described in Ref. [15]. All other data points were measured via Δ PL plotted on the right-side y axis of (B), with the left-side y axis linearly scaled. FIG. 4C is a Log-log plot of the NV XY8 decay in a TEM irradiation spot in sample A, highlighting the stretch exponent power α=⅔ in the early-time regime, as expected for a strongly interacting 2D spin system.

FIGS. 5A-5D illustrate the influence of doping time, temperature, and miscut on nitrogen incorporation. FIG. 5A is a Plot of nitrogen incorporation versus doping time, where samples are grouped by color according to the [¹⁵N₂]/[¹²CH₄] ratio. FIG. 5B is a SIMS profile of an (001) sample codoped with ¹³C before, during, and after introduction of ¹⁵N. The decreased ¹³C peak during nitrogen doping suggests a reduction in the diamond growth rate, which may allow for increased nitrogen areal density. FIG. 5C is a SIMS profile of a sample grown with four different doping temperatures, as indicated on the plot. In contrast to (001) growth, nitrogen shows a weakly increasing dependence with higher temperature. FIG. 5D is a Scatter plot of samples showing SIMS-measured nitrogen density (normalized by t_{d} and nitrogen gas content) versus polar miscut angle. No clear trend exists between miscut and nitrogen incorporation in (111) growth. Samples A-C referenced in the main text are indicated on the plot.

FIGS. 6A-6B illustrate characterization of 2D nature via SIMS and DEER. FIG. 6A is a SIMS depth profile of sample A (blue, dashed) and sample B (red, solid), showing thin confinement of the delta-doped layer. The FWHM of sample A is 5.8 nm and of sample B is 3.2 nm, and the areal densities are 1500 ppm nm for sample A and 1700 ppm nm for sample B. FIG. 6B is a Log-log plot of the DEER decay in sample A showing good agreement with an α=⅔ stretch exponent, indicating that the NVs probe a 2D P1 center bath.

FIG. 7. Influence of miscut on NV density. Plot of ΔPL, a proxy for NV density, divided by the areal density of nitrogen extracted from SIMS versus substrate miscut. Blue data represent as-grown NV concentrations, and yellow shows enhancement after annealing. ΔPL values are measured under 100-μW excitation, and all circular points are measured on the same confocal setup; square and triangle points are measured on a different setup and may be prone to increased error due to differences in the collection optics. Error bars represent the standard error of the mean of ΔPL measurements taken on different locations within the diamond sample.

FIGS. 8A-8C. Disorder-suppressed, dipolar-limited ODMR spectra of NV ensembles. FIG. 8A is a XY8ODMR pulse sequence schematic: NVs are initialized into either a bright (mₛ=0) state via a 532 nm laser pulse, or dark (mₛ=+1) state via an additional strong It pulse. FIG. 8B shows XY8-ODMR spectra, normalized as a fraction of total PL, for NV ensembles in (111)-oriented sample C and (001)-oriented sample D. Purple (orange) diamonds are measured spectra for Sample D for initialization into the bright (dark) states and cyan (red) circles are measured spectra for Sample C for initialization into the bright (dark) states. Solid lines are simulations of the mean field distribution as shown in FIG. 2E, incorporating various broadening mechanisms. FIG. 8C shows Spectra on a log-linear scale to highlight the spin orientation-dependent asymmetry in the (111) NV ensemble (red and cyan circles, sample C). The purple (001) sample D XY8-ODMR spectrum from (B) is reproduced for comparison. To demonstrate that the asymmetry is a fundamental property of (111)-oriented ensembles, we also display the dipolar-limited spectrum of other NV orientations in sample C (green squares). β is defined as the difference in normalized mean area under the curve between the left and right side of each spectrum and emphasizes the asymmetry of the (111) data.

FIGS. 9A-9B illustrate magnetic imaging with (111) NV ensembles. FIG. 9A is a Plot of the magnetic field produced by an Fe nanoparticle deposited on the diamond surface and encapsulated in type F objective oil. FIG. 9B is a Dipole simulation for the field produced by a 2-μm-diameter iron particle with a magnetic moment of 2.216μ B/atom. Field contours at ±0.1 mT are indicated by red and blue lines in both plots. A gray circle is drawn over the center of the particle where NV photoluminescence is quenched and ODMR contrast is depleted.

FIG. 10 is a schematic of a system using the device described herein.

FIG. 11 is a flowchart illustrating a method of operating or testing the device described herein.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

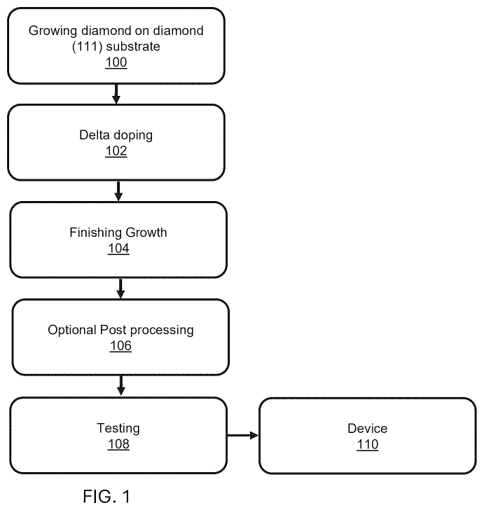

FIG. 1 is a flowchart illustrating a method of making a diamond layer including nitrogen vacancies. The method includes the following steps.

Block 100 represents growing a diamond epilayer on a (111) surface of diamond substrate, or on a miscut surface of a (111) diamond substrate. In typical embodiments, the step comprises using Plasma Enhanced Chemical Vapor Deposition (PECVD) to grow an isotopically purified diamond epilayer on a surface of a diamond substrate having a (111) orientation (or miscut thereof). Example PECVD growth conditions include, but are not limited to, using a 750 W plasma containing 400 sccm H₂ and 0.05-0.1% ¹²CH₄ held at 25 torr and ~770° C.

Block 102 represents delta-doping the epilayer with dopants in a 2D layer. An example nitrogen delta-doping period of growth comprises introducing a dopant gas flow along with the precursor gases into the PECVD reactor for a variable doping time (e.g., 0.5-20 minutes), e.g., at a temperature in a range of 600° C. to 800° C. The ratio of nitrogen to CH₄ (e.g., in a range of 10-25) and doping time can be varied to control the dopant density.

Block 104 represents finishing the growth of the diamond layer after the doping is ended.

Block 106 represents optionally performing various post processing steps, including but not limited to one or more of irradiation with electrons, annealing, and/or cleaning. Example electron irradiation (to create vacancies) is a dose of 7×10¹⁸ e−/cm², example annealing (to form NVs) includes using a two-step high-temperature annealing in vacuum (e.g., 400° C. for 2 hours and 850° C. for 4 hours) to promote vacancy diffusion and NV center formation and example surface cleaning uses a Tri-acid cleaning (H₂SO₄:HC₁O₄:H₂O₂) and a final 450° C. air anneal can be used to promote oxygen termination to help stabilize the NV-charge state.

Two dimensionality is defined as an inter-spin spacing of the dopants which is larger than the layer thickness. Example thicknesses of the dopant layer are in a range 2-50 nm in one or multiple layers. Example miscut angles are in a range of 0.5 degrees to 3 degrees with respect to the (111) plane. Example dopant density of the nitrogen atom dopants include, but are not limited to, up to 1.9×10⁴ ppm nm (e.g., in a range of 300 ppm nm-1.9×10⁴ ppm nm) and such that at least 4% of the dopant sites are converted to nitrogen vacancies.

In one or more embodiments, the thickness of the delta doped layer is defined as the full width at half maximum of the nitrogen concentration peak measured by SIMS, meaning the width of the peak measured at half the height of the peak maximum.

In one or more embodiments, SIMS also provides the nitrogen areal density of the delta doped layer by integrating the nitrogen concentration depth profile over the depth range of the layer. The integrated nitrogen areal density is expressed in units of ppm nm, which is the product of the nitrogen volume concentration in parts per million on an atomic basis and the layer thickness in nanometers, representing the total number of nitrogen atoms per unit area of the layer integrated over the layer thickness. Parts per million on an atomic basis means the ratio of nitrogen atoms to carbon host atoms in the diamond lattice multiplied by one million. The mean nearest neighbor spacing between nitrogen atoms within the plane of the delta doped layer is calculated from the SIMS measured nitrogen areal density in ppm nm.

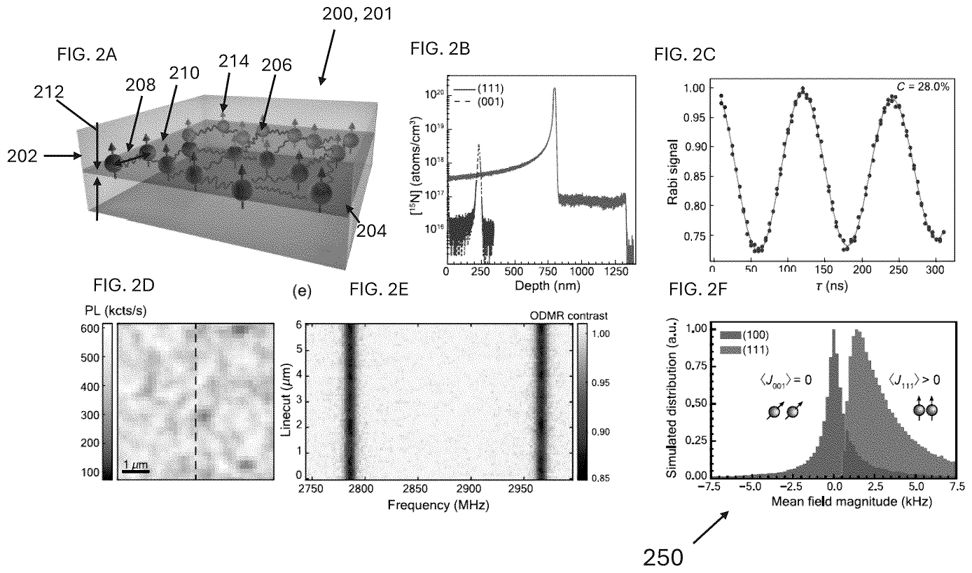

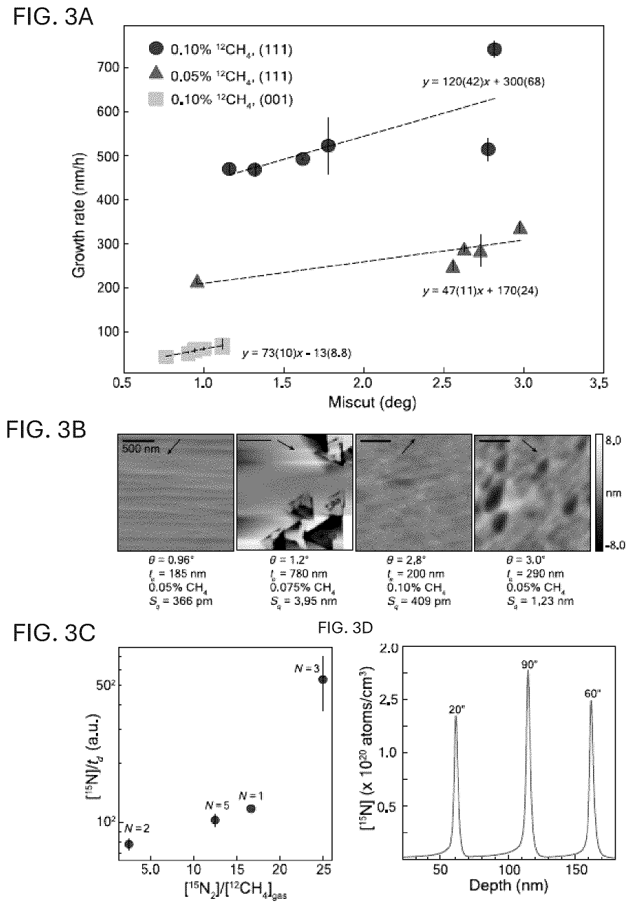

Block 108 represents optionally testing the dopant levels and/or presence of dipole interactions in the sample resulting from the nitrogen vacancies. FIG. 2B-2E illustrate various metrics for characterizing the doping. FIG. 2F shows the simulated dipolar interaction-induced mean field distribution for appropriately fabricated NV ensembles has an asymmetric distribution. FIG. 3b shows an asymmetry in XY8-ODMR spectra which is also signature of nonzero dipolar interactions.

A method of testing a sample using XY8-ODMR, comprises irradiating a sample comprising nitrogen vacancy (NV) centers with a pump sequence of rf pi pulses of alternating phase in order to decouple disorder as in a standard XY8 dynamical decoupling sequence;

Simultaneously, optically detected magnetic resonance is performed to obtain a disorder-suppressed spectrum representing a spin population in the sample; and observing whether there is an asymmetry in the lineshape of the spectrum. The asymmetry is associated with non-zero dipolar interactions of the NV ensemble.

Block 110 represents the end result, a device 200 or composition of matter 201 comprising a diamond layer 202 having a (111) orientation (or miscut thereof), wherein the diamond layer comprises a doped layer 204 comprising a two dimensional ensemble of nitrogen vacancy centers 206 characterized by a spacing 208 of nearest neighbor ones of the centers in a two dimensional plane 210 of the doped layer being larger than a thickness 212 of the doped layer and the spins 214 of the centers generating a non-zero dipolar induced mean field distribution.

In another embodiment, the device is further applied as a magnetic field sensor. In another embodiment, the device is further configured for entanglement enhanced metrology, e.g., by coupling the device with pulses configured for entangling the spins of the NV centers (e.g., to form spin squeezed states). The entangled spins or spin squeezed state can then be used to measure magnetic fields with reduced noise or for other applications.

In yet another embodiment, the device is further configured for quantum simulation.

The NV center concentration, dipolar induced mean field distribution, alignment of the spins, and/or spin states, proximity of the dopant layer to the surface can be tailored or configured for these various applications. Proximity of the dopant layer to the diamond surface can provide for enhanced spatial resolution.

### Example Device Characterization [61]

### Control of Nitrogen Incorporation

The experimental results demonstrate control over nitrogen incorporation during (111) growth and confinement of high density nitrogen into thin delta-doped layers. FIG. 2B shows nitrogen incorporation is enhanced by a factor of approximately 60 on the (111) plane as compared to the highest-density (001) sample grown with the same doping conditions. The (111) sample has an areal density of 1.9 (0.2)×10⁴ ppmnm [3.43 (0.04)×10¹⁴ atoms/cm²], as determined from integrating the secondary ion mass spectrometry (SIMS) data as in Ref. [15]. Increased dopant incorporation on the (111) plane is consistent with observations from three-dimensional doping studies [29,42,43], although these works observe a smaller enhancement of only 3-4 times.

It was found that the main control knobs over nitrogen density are the ratio of the source gases ([¹⁵N₂]/[¹²CH₄]) and the doping time (t_{d}). FIG. 3C shows nitrogen density, as determined with SIMS and normalized by t_{d}, versus ([¹⁵N₂]/[¹²CH₄]), highlighting greater incorporation with higher nitrogen concentration in the plasma. In this experiment, [[¹⁵N₂]/[¹²CH₄]] was not increased beyond 25 due to the limitations of the mass flow controller (although 25 is already larger than typical ratios [42,44]), although higher ranges are possible. FIG. 3C indicates the surface solubility limit for the (111) diamond surface was not reached, in contrast to observations in (001) diamond [25], leaving open the possibility of achieving even higher nitrogen densities in (111).

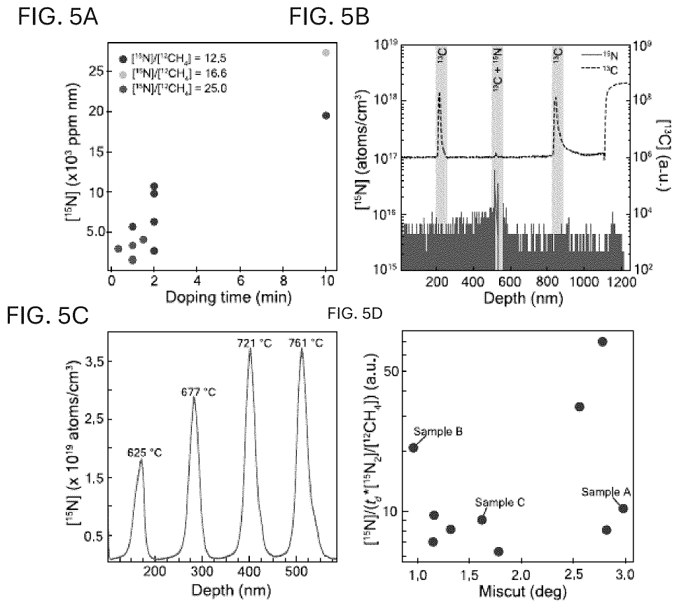

The thickness of the nitrogen layers can be controlled using doping time (e.g., reduced to a few nanometers for sufficiently short doping time). FIG. 3D shows three thin nitrogen layers in a single sample with doping times of 20, 60, and 90 s. Each layer was measured to be 4 nm thick, which gives an upper bound as the measured thickness is limited by the SIMS resolution in this case. Even for this overestimate, the two-dimensional nature holds as the spacing between spins is larger than the layer thickness. Lengthening the doping time allows increasing the nitrogen areal density while staying within the 2D limit, which may be afforded in part by a decreased growth rate during doping due to the high nitrogen content in the plasma [FIGS. 5A and 5B]. Even longer doping times lead to 3D spin systems. The relevant dimensionality of the dipolar interacting spin system can be probed via the decoherence dynamics of the spins themselves as in Refs. [15,16], wherein the stretch exponent of the coherence decay indicates the dimensionality of the spin bath. This technique was applied to verify the 2D nature of the dipolar spin bath in the fabricated (111) delta-doped samples. Finally, in contrast to (001) growth [45], (111) nitrogen incorporation shows a slight increase with higher doping temperature (similar to Ref [42]) and no significant dependence on the substrate miscut, also unlike (001) growth [41]. FIGS. 5C and 5D illustrate the effects of the temperature and miscut on nitrogen incorporation in (111), showing weakly increasing nitrogen incorporation with higher temperature (opposite trend to that for (001) and no clear trend for miscut and no preference for nitrogen sticking only at step-edge sites (For (001) growth, the substrate miscut sets the step-edge density which crucially impacts the nitrogen incorporation during step-flow growth)

### NV Center Alignment

Although preferential alignment of NVs during (111) growth has been previously studied, the present disclosure focused on a new regime targeting high densities (where NV-NV dipolar interactions dominate) and two dimensionality, which has not previously been demonstrated in (111) diamond. Prior studies investigated ppb-level NV incorporation that originates from low-concentration doping or impurity nitrogen in the hydrogen and methane source gases [34,35].

Reference observes NV densities up to 0.18 ppm (3.1×10¹⁶ atoms/cm³) as grown in (111) diamond, but they were determined via PL intensity, which is prone to overestimation due to non-NV fluorescent defects. Traditional methods to enhance the NV density include irradiation and annealing treatments, which come at the cost of reduced preferential alignment. A method to generate high-density, strongly interacting NV ensembles while preserving (111) alignment has not yet been demonstrated until the present disclosure.

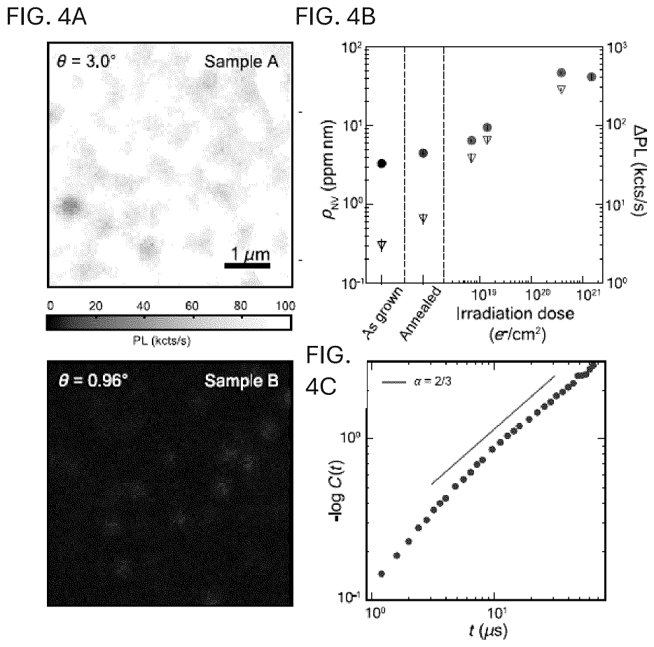

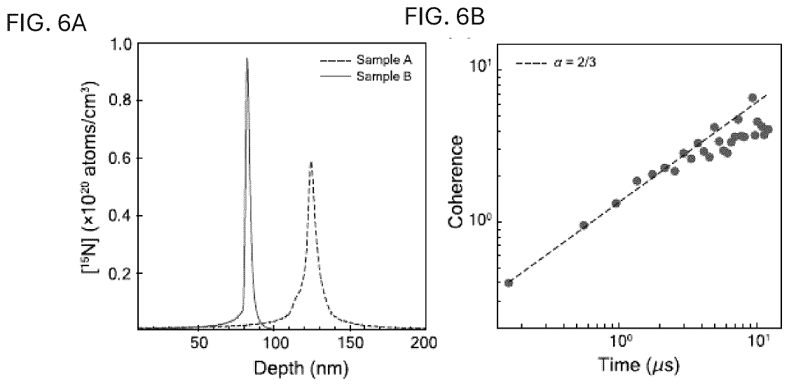

It was discovered that substrate miscut plays a surprisingly large role in the concentration of aligned NV centers that incorporate during diamond growth, in stark contrast to the observed lack of dependence of nitrogen incorporation on miscut. FIG. 4A shows scanning confocal PL images for samples A and B grown simultaneously with a doping time of one minute and differing only in substrate miscut of 3.0° and 0.96°, respectively. The images were taken immediately postgrowth and show clear increased PL from sample A. Furthermore, all of the NVs display preferential alignment, as shown in the optically detected magnetic resonance (ODMR) spectra of sample A in FIG. 2C. The grown-in, aligned NV density in sample A was quantitively estimated using a decoherence-based method as described in Ref. and an average density of ρ_{NV}=4.5±0.5 ppmnm was extracted. Without irradiation, this density is already similar to the highest NV densities achieved via irradiation and annealing of (001) samples [15,16]. FIG. 4B shows how NV concentration in samples A and B evolved with irradiation and annealing, achieving densities up to 47 and 28 ppm nm, respectively. The NV density in sample B approaches a similar level to sample A after irradiation, consistent with the comparable nitrogen content seen via SIMS in the two samples (see FIG. 6A]). The trend of increasing grown-in NV density with miscut angle holds for all additional samples measured, as shown in FIG. 6C.

### Investigation of the Strongly Interacting, Two Dimensional Nature of the High-Density NV Layers.

FIG. 4C shows a measurement of the stretch exponent n of the XY8 coherence decay e^{-(t/T}^{₂}⁾^{ⁿ} with n=⅔ as expected for a 2D dipolar-interacting ensemble at early times (where t<τ_{c}, the correlation time of the ensemble) [16]. FIG. 6B shows the dimensionality of the nitrogen is further corroborated by an n=⅔ stretch exponent in the double electron-electron resonance (DEER) decay, which probes neutrally charged substitutional nitrogen [N_{S}⁰] or P1 centers. From DEER, the density of P1 centers was also extracted as ρ_{P1}=130±19 ppm nm. Dividing ρ_{NV}/ρ_{P1} gives the asgrown NV yield in sample A as approximately 4%. Thus, by using miscut as a tuning knob during growth achieved a strongly interacting, aligned 2D NV ensemble where NV dipolar interactions dominate due to the high ratio of NV to nitrogen.

### Lineshape Characterization and Characterization of (111) NV-NV Dipolar Interaction.

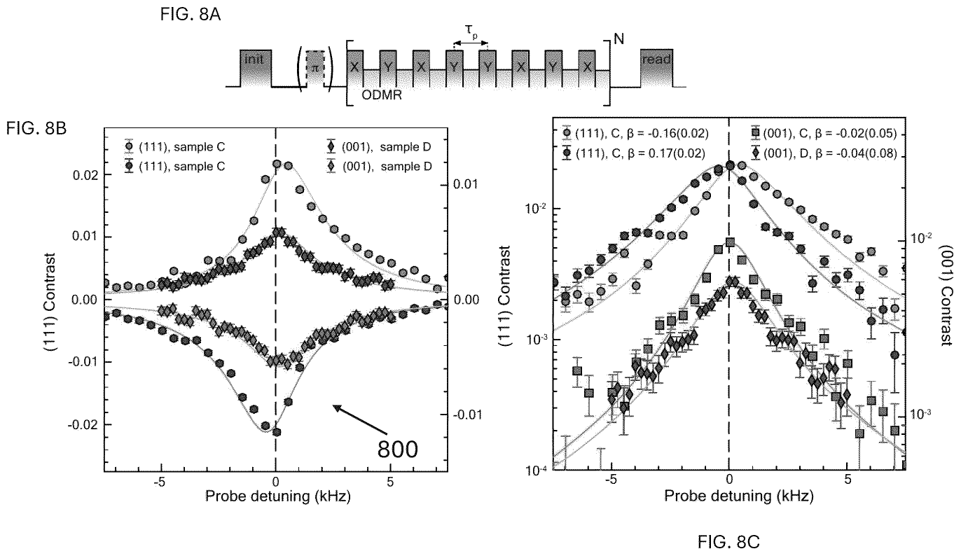

To experimentally access the dipolar-limited line shape of this distribution, a new technique, termed XY8-ODMR, was used and designed to suppress disorder during ODMR. FIG. 8A shows this measurement first uses an XY8-style “pump” sequence to resonantly drive and decouple the NV ensemble from sources of disorder in the surrounding lattice. Under this drive, the remaining sources of broadening for the NV ensemble line shape are dominated by dipolar interactions, which are not affected by the pump sequence. Simultaneous to the XY8 drive, a weak “probe” rf It pulse (analogous to the It pulse used in a conventional pulsed ODMR sequence [52]) was delivered. Varying the frequency of the probe It pulse and monitoring the resulting spin population obtains a disorder-suppressed equivalent of a pulsed ODMR spectrum (an “XY8-ODMR” spectrum) that is not linewidth limited by disorder (e.g., due to inhomogeneous strain or coupling to other defects) but rather primarily by dipolar interactions and power broadening. In this regime, the measured XY8-ODMR spectrum line shape is a direct measure of the distribution of dipolar couplings in the ensemble.

FIGS. 8C and 8D show an asymmetric line shape for a (111)-irradiated NV ensemble (sample C) compared to a symmetric line shape for (001) (sample D). The other NV orientations [not normal to the 2D plane, as in an (001)-oriented diamond] in sample C were also measured to exhibit symmetric line shape, as expected. The sign of the asymmetry observed in the (111) ensemble flips when the spins are initialized into the opposite spin state, demonstrating that the source of the mean field is the spins themselves. Altogether, the asymmetry observed here highlights a signature of the uniformly positive dipolar interactions in (111) that are crucial for further entanglement-enhanced metrology and quantum simulation.

The asymmetric line shape in an ODMR measurement is a direct characterization of the uniformly positive dipolar interaction unique to a (111) 2D NV ensemble. FIG. 2E shows simulated dipolar-induced mean field distributions for (001) and (111) 2D NV ensembles using the experimentally determined density and thickness (Table II) illustrating the nonzero average interactions present in (111).

### Magnetic Sensing

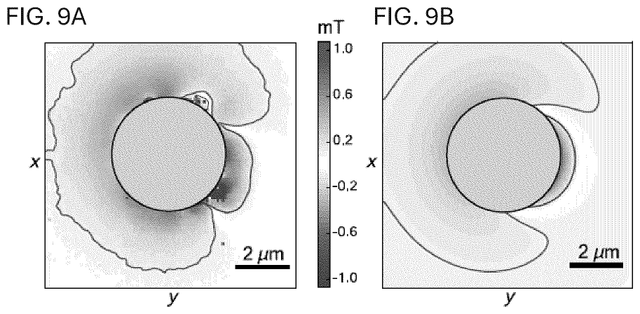

FIGS. 9A and 9B demonstrate magnetic-field imaging of a micrometer-scale Fe nanoparticle deposited atop diamond sample A with approximately 120-nm-deep, grown-in (unirradiated) NV centers. ODMR is performed over a 10×10 μm² region of NV centers, taking 100×100 pixels and sweeping the frequency from 2750 to 2850 MHz. The resulting spatial magnetic-field plot is shown in FIG. 9A, with contour lines indicated at ±0.1 mT. A gray circle is drawn over the center of the particle because in this region the ODMR contrast is depleted and the NV photoluminescence is quenched. FIG. 9B shows a simulated dipole field due to a 2-μm-diameter Fe particle, assuming a magnetic moment of 2.216μ B/atom, and a 2D ensemble of (111) NV sensors 120 nm away. The dipole orientation is simulated with a polar angle θ=162° (into the page) and azimuthal angle φ=164° (in the x-y plane). Similar dipole contours are drawn at ±0.1 mT. The simulated field is approximately 100× smaller than expected, which could be due to increased standoff from the oil or smaller than expected particle radius. This demonstration shows that high-density (111)-aligned NVs as described herein can provide a platform for applications in ensemble magnetometry.

A volume-normalized ac sensitivity of η_{ac}=810pTμm^{3/2} Hz^{-1/2} was calculated for an electron irradiated spot on sample B (7×10¹⁸ e⁻/cm²). With reasonable improvements to photon collection efficiency, namely, count rates of 150 kcounts/see per NV can be achieved with, e.g., nanopillars. With other parameters identical to those measured using the setup on this sample, η_{ac}=153pTμm^{3/2} Hz^{-1/2} is projected. The volume-normalized sensitivities obtained are improvements over prior reports of NV ensembles in 3D (001) samples [9,27,47] and 3D (111) samples [48]. Further improvements to sensitivity can be gained by applying dipolar-decoupling sequences such as DROID-60 [9].

In addition to high sensitivities, the 2D nature of these ensembles offers an important advantage over conventionally implanted NV ensembles that exhibit a large spread in depths (10 s-100 nm for target depths of 10-100 nm) [15,49], making quantitative analysis of magnetic signals challenging, in particular for NV-based noise spectroscopy as well as for thin magnetic samples. Dipolar-driven entanglement-enhanced sensing schemes [11,50,51] may depend crucially on dense, 2D (111) ensembles in which dipolar interactions do not average to zero over an ensemble.

### Methods for the Samples Characterized Herein

### PECVD Diamond Growth

Diamond substrates were obtained by slicing (001) oriented electronic-grade CVD substrates (Element Six Ltd.) along the (111) plane and superpolishing was by Applied Diamond, Inc. to achieve a surface roughness of <500 μm. Prior to growth, the miscut angle was measured using x-ray diffractometry rocking curves about the (111) omega peak, and surface roughness was verified with AFM. PECVD growth was performed in a SEKI SDS6300 reactor using a 750-W plasma containing 400-sccm H₂ and 0.05%-0.1% ¹²CH₄ held at 25 torr and approximately 770° C. according to a pyrometer. These growth conditions result in a 99.998% ¹²C isotopically purified epilayer of variable thickness dependent on the growth time and substrate miscut. During the nitrogen delta-doping period of growth, ¹⁵N₂ gas (1.25% of the total gas content) was introduced into the chamber for a variable doping time of 0.5-10 min. Optical emission spectroscopy was used to monitor the plasma species throughout growth, specifically the H-alpha emission line and CN radicals. After growth, SIMS was used to estimate the isotopic purity, epilayer thickness, and properties of the delta-doped layer. SIMS analysis was performed in-house with conditions as outlined previously in Ref. [15].

### Post Growth Processing

Electron irradiation was performed with a TEM (ThermoFisher Talos F200X G2) to create locally enhanced NV concentrations inside the irradiated region [56]. Afterward, the samples underwent subsequent annealing at 400° C. for 2 h and 850° C. for 4 h in a vacuum furnace (4e-8 torr) to promote vacancy diffusion and NV formation. After irradiation and annealing, the samples were cleaned in a boiling triacid solution (1:1:1H₂SO₄:H₂O₂:HClO₄) and annealed at 450° C. for 4 h in air to remove surface contaminants and promote oxygen termination which stabilizes the negative NV-charge state.

### NV Center Characterization

All NV center measurements were performed on a homebuilt confocal microscope using a 532-nm diode laser and an external magnetic field of approximately 300-370G aligned along the diamond (111) axis unless otherwise specified. A cutoff filter of 640 nm was placed in the collection path before the avalanche photodiode to eliminate background fluorescence from NV °. RF signals were delivered through a gold antenna fabricated on a glass slide and placed underneath the diamond.

TABLE I
Details of samples characterized herein. Three center dots indicate
unmeasured quantities. “As-grown” measurements are taken
on the unirradiated regions of the diamond, but the samples have
been through an annealing process before characterization.

| | Sample | Sample | Sample | Sample |
|---|---|---|---|---|
| | A | B | C | D |
| Crystal orientation | (111) | (111) | (111) | (001) |
| Miscut, θ (deg) | 3.0 | 0.96 | 1.6 | 1.1 |
| [¹⁵N₂]/[¹²CH₄] ratio | 25 | 25 | 12.5 | 25 |
| Doping time (min) | 1 | 1 | 10 | 10 |
| SIMS nitrogen layer | 5.8 | 3.2 | 17 | 8.8 |
| thickness (nm) | | | | |
| SIMS nitrogen areal | 1500 | 1700 | 19000 | 200 |
| density (ppm nm) | | | | |
| SIMS nitrogen volume | 260 | 520 | 1100 | 23 |
| density (ppm) | | | | |
| As-grown NV density | 4.5 | 0.65 | . . . | . . . |
| (ppm nm) | | | | |
| As-grown DEER P1 | 126 | 6 | . . . | . . . |
| density (ppm nm) | | | | |
| As-grown NV/P1 ratio | 0.04 | 0.11 | . . . | . . . |
| TEM irradiation dose | 4e19 | . . . | 6e19 | 7e20 |
| (e⁻/cm²) | | | | |
| TEM DEER P1 density | 111 (2e19 | . . . | 64 | 85 |
| (ppm nm) | dose) | | | |
| TEM NV density | 10 | . . . | 8 | 19 |
| (ppm nm) | | | | |
| TEM NV/P1 ratio | 0.09 | . . . | 0.13 | 0.22 |

### XY8-ODMR Protocol

As depicted in FIG. 8A, the protocol for probing dipolar interactions starts with pumping the NV centers into the mₛ=0 state with a pulse of 532-nm light (power Pₗₐₛₑᵣ, duration tᵢ). To initialize the NV centers into the mₛ=+1 states, a resonant microwave It pulse at a Rabi frequency of Lₚᵤₘₚ and drive frequency f_{NV} was used. The same microwave source was used to perform dynamical decoupling and remove as much disorder as possible. For an XY8-N decoupling sequence, the t-pulse spacing τₚ was decreased (to shift the NV coherence filter function to higher frequencies) until the measured coherence under the dynamical decoupling drive saturated, indicating that disorder was suppressed as much as possible. Having set τₚ optimally, the probe low-power ODMR drive was swept across a center frequency f_{NV}+(¼τₚ) with power Ω_{probe}. This offset center frequency was necessary to properly account for the observed modulated resonant frequency of NVs in the toggling frame of the XY8 drive. The number of repetitions N were set such that the length of the dynamical decoupling sequence 8Nτₚ was equal to the length of the ODMR π pulse π/Ω_{probe}. Finally, the spin population was read out with a 532-nm laser pulse (duration tᵣ). The final sequence parameters used for each sample were:
(i) Sample C: tᵢ=40 μs, τₚ=540 ns, tᵣ=1000 ns, Pₗₐₛₑᵣ=100 μW, Lₚᵤₘₚ=2π×12.5 MHz, and Ω_{probe}=2π×0.97 kHz.
(ii) Sample D: tᵢ=40 μs, τₚ=1.032 μs, tᵣ=400 ns, Pₗₐₛₑᵣ=180 μW, Ωₚᵤₘₚ=2π×16 MHz, and Ω_{probe}=2π×0.75 kHz.

### Example System

As used herein the NV center has a spin triplet ground state comprising three spin sublevels designated mₛ=0, mₛ=+1, and mₛ=−1. The mₛ=0 sublevel and the mₛ==1 sublevels are separated in energy by the zero field splitting of approximately at zero magnetic field. Application of a static magnetic field along the NV axis splits the mₛ=+1 and mₛ=−1 sublevels further via the Zeeman effect, producing two distinct resonance frequencies for the mₛ=0 to mₛ=+1 and mₛ=0 to mₛ=−1 transitions. The microwave transitions driven in the ODMR and XY8-ODMR protocols described herein are spin transitions within the ground state triplet manifold between the mₛ=0 sublevel and the mₛ=+1 or mₛ=−1 sublevel. Optical initialization of the NV centers into the mₛ=0 sublevel is achieved by illumination with a 532 nm laser, which drives the optical transition from the ground state triplet to an excited state triplet followed by preferential relaxation to the mₛ=0 sublevel. Readout of the spin state is achieved by monitoring the fluorescence intensity during a laser pulse, with mₛ=0 producing higher fluorescence than mₛ=+1 or mₛ=−1 due to the same spin-dependent intersystem crossing mechanism.

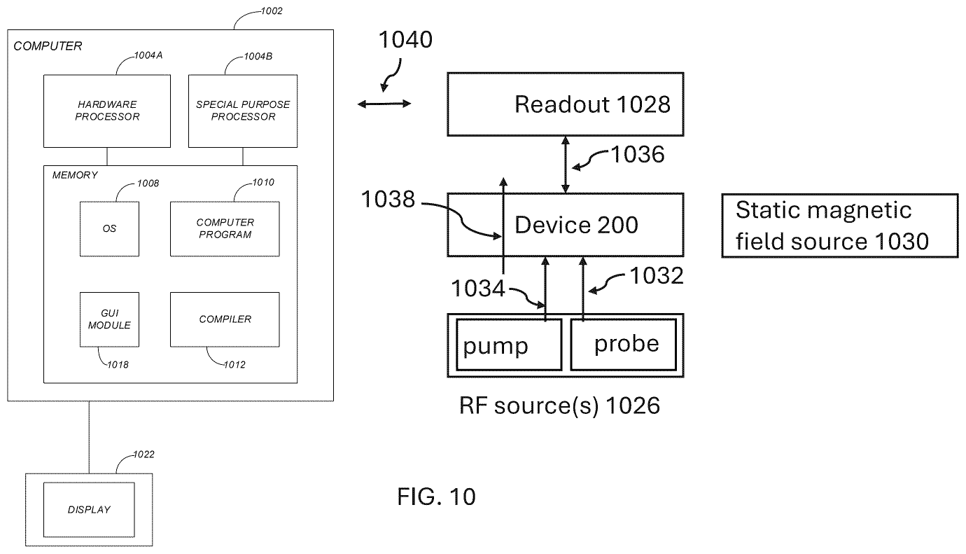

FIG. 10 illustrates an example system or apparatus for using, testing, or measuring the device of any of the embodiments described herein. The system includes the device 200, a static magnetic field source 1030 (e.g., electromagnet or magnet) outputting a static magnetic field 1038 aligned along the (111) axis of the device; one or more radio frequency sources (e.g., comprising antennas) 1026 for irradiating the device with pump electromagnetic radiation 1034 (e.g., dynamical decoupling pulses 802) and probe electromagnetic radiation 1032; a readout system 1028 (e.g., comprising confocal microscope, laser for outputting readout beam, and photodiode for detecting fluorescence) for collecting and/or generating readout beams 1036 (e.g., fluorescence in response to a readout beam); and a computer system 1002 coupled 1040 to the readout system, the RF source(s); and optionally the magnetic field source.

In one embodiment, the readout laser is a 532 nm wavelength readout laser tuned an intra-defect optical transition of the NV center between localized states within the bandgap. The fluorescence collected beyond 640 nm corresponds to phonon sideband emission from the NV-zero phonon line at 637 nm, which is the radiative relaxation between the excited and ground defect states within the bandgap. These are trap state transitions within the bandgap.

Because the NVs are aligned along one axis in (111), all NVs share essentially the same resonance frequency and the ODMR spectrum shows clean single-orientation resonance with no other NV orientations visible as shown in FIG. 2E. This simplifies the microwave/RF source requirements as only one transition frequency needs to be driven.

The dynamic decoupling sequence (e.g., XY8-ODMR) protocol is specifically designed and applied to reveal the asymmetric dipolar line shape unique to (111). The pump Rabi frequencies and probe Rabi frequencies are specifically tuned to suppress disorder and access the dipolar distribution. Typically the pump Rabi frequency is selected so that pump drives spin flips faster than the decoherence rate (Ωₚᵤₘₚ>>1/T2* where T2* is the dephasing time set by disorder). The probe is weak enough to not perturb the disorder suppressed state created by the pump and is set to be smaller than the dipolar linewidth so that Ωₚᵤₘₚ>>dipolar linewidth>>Ω_{probe}. The frequency of the probe is swept across all (or a range) of the resonance frequencies of the NV centers so that small magnetic field induced resonance frequency shifts can be resolved with maximum precision (alternatively, the probe can induce spin flips when the resonance frequencies vary across the ensemble due to magnetic field induced variations).

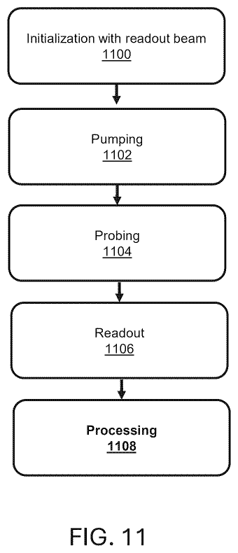

FIG. 11 is a flowchart illustrating a method of testing or using/operating a sample/device according to one or more embodiments, comprising the following steps.

Block 1100 represents initialization of the NV centers, e.g., in the mₛ=0 state.

Block 1102 represents irradiating a sample comprising nitrogen vacancy (NV) centers in a surrounding lattice with a pump sequence of electromagnetic radiation to resonantly drive the NV centers into an initial spin state and decouple the NV ensemble from sources of disorder in the surrounding lattice.

Block 1104 represents simultaneously with the pump sequence, irradiating the sample with a probe RF pi pulse of varying frequency, wherein frequencies of the probe resonant with a transition between an mₛ=0 to an mₛ=+/1 state may flip the initial spin state between the mₛ=0 and the mₛ=+/1 state.

Block 1106 represents collecting a readout signal from the device, comprising exciting the sample with a readout beam generating fluorescence from the sample to obtain a disorder-suppressed spectrum representing a spin population in the sample.

Block 1108 represents processing/measuring the signal, comprising observing whether there is an asymmetry in the lineshape of the spectrum whose sign flips when the initial spin state is flipped and associating the asymmetry with non-zero dipolar interactions of the NV ensemble.

In one magnetic sensing embodiment, the pump provides dynamical decoupling to prepare the NV centers in a regime where disorder is suppressed (e.g., the asymmetric lineshape would be observable), the static magnetic field applied to generate Zeeman splitting of the mₛ states and the NV centers are initialized in one of the mₛ states defining a resonance frequency of the NV centers. In the presence of a magnetic field being sensed, the resonance frequency of NV centers is shifted proportionally to the local magnetic field projection along the (111) axis, so that NVs experiencing a stronger local field have a larger resonance frequency shift and the magnetic field may creates a spatial distribution of resonance frequencies across the ensemble.

The probe frequency (e.g., pi pulse) is set to a specific value in the sweep so that NVs whose resonance frequency matches the probe frequency get efficiently flipped (e.g., to mₛ==1) and NVs whose resonance frequency does not match the probe frequency remain in mₛ=0. NVs whose resonance was shifted away from the probe frequency by the magnetic field are not flipped by the probe and they remain in mₛ=0 and emit bright fluorescence in readout. NVs whose resonance was not shifted or shifted to match the probe frequency are flipped to mₛ=±1 and may emit dim fluorescence in readout. The magnetic sensor can therefore be used for spatial imaging where each pixel in the confocal scan of the fluorescence brightness reflects how many NVs in that spot were flipped by the probe and sweeping the probe frequency across the resonance range and the readout across the device maps out the full magnetic field distribution.

The frequency at which each pixel transitions from bright to dim gives the local field strength at that position.

The magnetic sensing can be used for metrology applications including, but not limited to, AC or DC magnetic field sensing biological sensing (e.g., optical magnetic detection of single neuron action potentials, magnetic fields from biological currents, with high sensitivity and spatial resolution relevant for neural magnetic imaging, condensed matter sensing (probing condensed matter physics with NV magnetometry, e.g., nanoscale imaging of magnetic domain walls.

Entanglement enhanced metrology can be implemented by for sensing beyond standard quantum limit sensing. The pump can also be used to entangle the spins of the NV centers (e.g., via spin squeezing) and the magnetic sensing can proceed using the probe sweep and readout beams.

In a quantum simulation embodiment, the NV center spin states can be prepared in a well defined initial state of interest, then allowed to evolve under an Hamiltonian of interest (e.g., subject to the environment), and the state can be measured (e.g., using metrology/magnetic sensing as described herein after some evolution time. The protocol can be repeated many times to build up statistics of the quantum dynamics and information about the underlying physics/system or system coupled to the device can be extracted from the measured evolution.

### Example Embodiments

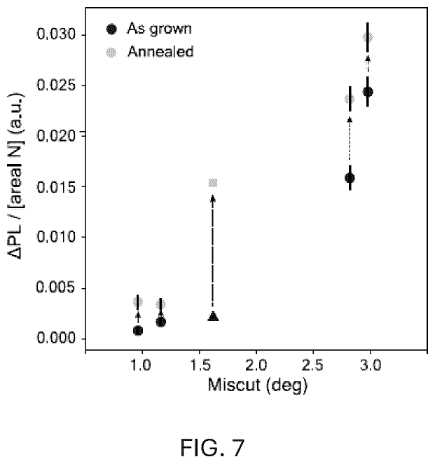

Illustrative embodiments of the inventive subject matter disclosed herein include, but are not limited to, the following (referring to FIGS. 1-11).
1. A composition of matter 201, comprising a diamond layer 202 having a (111) orientation or miscut thereof, wherein the diamond layer comprises a doped layer 204 comprising a two dimensional ensemble of (e.g., nitrogen) 206 vacancy centers.
2. The composition of matter of clause 1, wherein the two dimensional ensemble is characterized by a spacing or all spacings 208 of nearest neighbor ones of the centers in a two dimensional plane, or an area the two dimensional plane, of the doped layer being larger than a thickness 212 of the doped layer (e.g., at any point in the area).
3. The composition of matter of clause 1 or clause 2, wherein the two dimensional ensemble is characterized by the spins 214 of the centers generating a non-zero dipolar induced mean field distribution 250.
4. The composition of matter of any of the clauses 1-3 wherein the dipolar induced-induced mean field distribution 250 is asymmetric about zero, showing a net positive mean field distribution.
5. The composition of matter of any of the clauses 3-4, wherein the mean field distribution is characterized by an asymmetric spectrum 250, 800 with a sign flip when the spins are initialized in an opposite state, as measured by a XY8-ODMR pump probe measurement.
6. The composition of matter of any of the clauses 1-5, wherein the dopant layer comprises a dopant density of up to a value that maintains a condition of two-dimensionality, as defined in any of the clauses 1-5.
7. The composition of matter of any of the clauses 1-6, wherein the dopant layer is two dimensional as defined herein or in any of the clauses.
8. The composition of matter of clauses 3-7 wherein the dipolar induced-induced mean field distribution is characterized by an asymmetric lineshape 800, 250 measuring response as a function of RF frequency
9. The composition of matter of clause 8 wherein the asymmetric lineshape that measured in the presence of a dynamical decoupling pump wherein the asymmetry is on one side of the response when the NV centers are initialized in an mₛ=0 state and on the other side of the lineshape when the NV centers are initialized in the mₛ=+1 or mₛ=−1 states.
10. The composition of matter of clause 8 or 9 wherein the lineshape is asymmetric about a zero detuning of a frequency of a probe with respect to the frequency of the pump when the probe is measuring the lineshape.
11. The composition of matter of any of the clauses 3-10, wherein the mean field distribution is characterized by an asymmetric spectrum with a sign flip when the spins are initialized in an opposite state, as measured by a pump probe measurement when the ensemble is dynamically decoupled from sources of disorder in the surrounding lattice.
12. The composition of matter of any of the clauses 1-11, wherein the dopant layer comprises a dopant density of nitrogen atoms up to a value that maintains a condition of two-dimensionality, as defined in any of the clauses 1-11
13. The composition of matter of any of the clauses 1-12, wherein the dopant layer is two dimensional as characterized by the stretch exponent n of a coherence decay e^{-(t/T}^{₂}⁾^{ⁿ} measurement of n=⅔ where T₂ is the coherence time measured during dynamical decoupling.
14. A magnetic field sensor comprising the composition of matter of any of the clauses 1-13.
15. A sensor configured for entanglement-enhanced metrology or quantum simulation comprising the composition of matter of any of the clauses 1-15
16. A method of making a composition of matter, comprising:
growing a diamond epilayer on a 111 orientation or miscut surface of a (111) diamond substrate; and
delta-doping the epilayer with (e.g., nitrogen) dopants in a dopant layer;
   wherein:
the miscut (if any) and a dopant concentration of nitrogen dopants are selected so that:
the nitrogen dopants convert to a two dimensional ensemble of nitrogen vacancy centers in the dopant layer.
17. The method of clause 16, wherein the two dimensional ensemble is characterized by
a spacing of nearest neighbor ones of the centers in a two dimensional plane of the dopant layer being larger than a thickness of the dopant layer and
the spins of the centers generating a non-zero dipolar induced mean field distribution.
18. The method of clause 16, wherein the miscut (if any) and dopant concentration are selected so that:
all spacings of nearest neighbor ones of each of the centers in an area of a two dimensional plane of the dopant layer are larger than a thickness of the dopant layer at each point in the area, and/or
the spins of the centers generate a non-zero dipolar induced mean field distribution.
19. The method of clause 16, 17, or 18, further comprising:
in a PECVD reactor, growing the diamond epilayer on a surface of a diamond substrate having a 111 orientation, under conditions to form a ¹²C isotopically purified epilayer of diamond; and
during a nitrogen delta-doping period of growth forming the dopant layer, introducing a dopant gas flow into the PECVD reactor together with the precursors flow.
20. The method of any of the clauses 16-19 wherein the surface normal of the surface is in a range of 0-3 degrees with respect to a surface normal of the 111 plane and/or the delta doping introduces a dopant density of nitrogen atoms in a range of 300-1.9×10⁴ ppm nm.
21. A method of testing a sample, comprising:
irradiating a sample comprising nitrogen vacancy (NV) centers in a surrounding lattice with a pump sequence of electromagnetic radiation to resonantly drive the NV centers into an initial spin state and decouple the NV ensemble from sources of disorder in the surrounding lattice;
simultaneously with the pump sequence, irradiating the sample with a probe RF pi pulse of varying frequency, wherein frequencies of the probe resonant with a transition between an mₛ=0 to an mₛ=+/1 state may flip the initial spin state between the mₛ=0 and the mₛ=+/1 state;
exciting the sample with a readout beam generating fluorescence from the sample to obtain a disorder-suppressed spectrum representing a spin population in the sample;
observing whether there is an asymmetry in the lineshape of the spectrum whose sign flips when the initial spin state is flipped and
associating the asymmetry with non-zero dipolar interactions of the NV ensemble.
11. The method of clause 21 testing or operating the sample comprising the composition of matter of any of the clauses 1-15.
12. The method of any of the clauses 16-20 making the composition of matter of any of the clauses 1-15.
13. A device comprising the composition of matter of any of the clauses 1-15.

An apparatus, system, or device configured for performing the method/testing of clause 21

The method of clause 21, wherein the pump sequence is a dynamical decoupling sequence comprising XY8-ODMR or DROID.

### ADVANTAGES AND IMPROVEMENTS

As most NV center-based companies are focused on quantum sensing, a key commercial advantage of two-dimensional spin ensembles in (111)-oriented diamond is their reproducibly high magnetic field sensitivity. Without applying any advanced measurement procedures, the samples can be used in simple DC or AC magnetic field sensing and offer many advantages over standard (100)-oriented diamond NV sensors. Beyond standard sensing applications, our invention has also demonstrated utility in entanglement-enhanced sensing (such as spin squeezing), which opens the door to a new regime of sensing beyond the standard quantum limit and may yield immense commercial gain over standard sensing schemes.

### REFERENCES

The following references are incorporated by reference herein
[1] F. Casola, T. van der Sar, and A. Yacoby, Probing condensed matter physics with magnetometry based on nitrogen-vacancy centres in diamond, Nat. Rev. Mater. 3, 17088 (2018).
[2] J.-P. Tetienne, T. Hingant, J.-V. Kim, L. Herrera Diez, J.-P. Adam, K. Garcia, J.-F. Roch, S. Rohart, A. Thiaville, D. Ravelosona, and V. Jacques, Nanoscale imaging and control of domain-wall hopping with a nitrogen-vacancy center microscope, Science 344, 1366 (2014).
[3] J. F. Barry, M. J. Turner, J. M. Schloss, D. R. Glenn, Y. Song, M. D. Lukin, H. Park, and R. L. Walsworth, Optical magnetic detection of single-neuron action potentials using quantum defects in diamond, Proc. Natl. Acad. Sci. U.S.A. 113, 14133 (2016).
[4] F. Dolde, I. Jakobi, B. Naydenov, N. Zhao, S. Pezzagna, C. Trautmann, J. Meijer, P. Neumann, F. Jelezko, and J. Wrachtrup, Room-temperature entanglement between single defect spins in diamond, Nat. Phys. 9, 139 (2013).
[5] B. Hensen, H. Bernien, A. E. Dréau, A. Reiserer, N. Kalb, M. S. Blok, J. Ruitenberg, R. F. L. Vermeulen, R. N. Schouten, C. Abellán, W. Amaya, V. Pruneri, M. W. Mitchell, M. Markham, D. J. Twitchen, D. Elkouss, S. Wehner, T. H. Taminiau, and R. Hanson, Loophole-free Bell inequality violation using electron spins separated by 1.3 kilometres, Nature (London) 526, 682 (2015).
[6] C. E. Bradley, J. Randall, M. H. Abobeih, R. C. Berrevoets, M. J. Degen, M. A. Bakker, M. Markham, D. J. Twitchen, and T. H. Taminiau, A ten-qubit solid-state spin register with quantum memory up to one minute, Phys. Rev. X 9, 031045 (2019).
[7] S. B. van Dam, J. Cramer, T. H. Taminiau, and R. Hanson, Multipartite entanglement generation and contextuality tests using nondestructive three-qubit parity measurements, Phys. Rev. Lett. 123, 050401 (2019).
[8] T. Xie, Z. Zhao, X. Kong, W. Ma, M. Wang, X. Ye, P. Yu, Z. Yang, S. Xu, P. Wang, Y. Wang, F. Shi, and J. Du, Beating the standard quantum limit under ambient conditions with solid-state spins, Sci. Adv. 7, cabg9204 (2021).
[9] H. Zhou, J. Choi, S. Choi, R. Landig, A. M. Douglas, J. Isoya, F. Jelezko, S. Onoda, H. Sumiya, P. Cappellaro, H. S. Knowles, H. Park, and M. D. Lukin, Quantum metrology with strongly interacting spin systems, Phys. Rev. X 10, 031003 (2020).
[10] S. Choi, N. Yao, and M. Lukin, Quantum metrology based on strongly correlated matter, arXiv: 1801.00042.
[11] M. Block, B. Ye, B. Roberts, S. Chern, W. Wu, Z. Wang, L. Pollet, E. J. Davis, B. I. Halperin, and N. Y. Yao, A universal theory of spin squeezing, Nat. Phys. 20, 1575 (2024).
[12] D. H. Reich, T. F. Rosenbaum, and G. Aeppli, Glassy relaxation without freezing in a random dipolar-coupled Ising magnet, Phys. Rev. Lett. 59, 1969 (1987).
[13] S. Ghosh, R. Parthasarathy, T. Rosenbaum, and G. Aeppli, Coherent spin oscillations in a disordered magnet, Science 296, 2195 (2002).
[14] J. Rodriguez, A. A. Aczel, J. P. Carlo, S. R. Dunsiger, G. J. MacDougall, P. L. Russo, A. T. Savici, Y. J. Uemura, C. R. Wiebe, and G. M. Luke, Study of the ground state properties of LiHoₓY₍₁₋ₓ₎F₄ using muon spin relaxation, Phys. Rev. Lett. 105, 107203 (2010).
[15] L. B. Hughes, Z. Zhang, C. Jin, S. A. Meynell, B. Ye, W. Wu, Z. Wang, E. J. Davis, T. E. Mates, N. Y. Yao, K. Mukherjee, and A. C. Bleszynski Jayich, Two-dimensional spin systems in PECVD-grown diamond with tunable density and long coherence for enhanced quantum sensing and simulation, ΔPL Mater. 11, 021101 (2023).
[16] E. J. Davis, B. Ye, F. Machado, S. A. Meynell, W. Wu, T. Mittiga, W. Schenken, M. Joos, B. Kobrin, Y. Lyu, Z. Wang, D. Bluvstein, S. Choi, C. Zu, J. A. C. B., and N. Y. Yao, Probing many-body dynamics in a two-dimensional dipolar spin ensemble, Nat. Phys. 19, 836 (2023).
[17] N. Y. Yao, C. R. Laumann, S. Gopalakrishnan, M. Knap, M. Müller, E. A. Demler, and M. D. Lukin, Many-body localization in dipolar systems, Phys. Rev. Lett. 113, 243002 (2014).
[18] A. L. Burin, Many-body delocalization in a strongly disordered system with long-range interactions: Finite-size scaling, Phys. Rev. B 91, 094202 (2015).
[19] D. A. Abanin, E. Altman, I. Bloch, and M. Serbyn, Colloquium: Many-body localization, thermalization, and entanglement, Rev. Mod. Phys. 91, 021001 (2019).
[20] N. Y. Yao, M. P. Zaletel, D. M. Stamper-Kurn, and A. Vishwanath, A quantum dipolar spin liquid, Nat. Phys. 14, 405 (2018).
[21] H. Zou, E. Zhao, and W. V. Liu, Frustrated magnetism of dipolar molecules on a square optical lattice: Prediction of a quantum paramagnetic ground state, Phys. Rev. Lett. 119, 050401 (2017).
[22] N. Tokuda, H. Umezawa, T. Saito, K. Yamabe, H. Okushi, and S. Yamasaki, Surface roughening of diamond (001) films during homoepitaxial growth in heavy boron doping, Diam. Relat. Mater. 16, 767 (2007).
[23] F. K. de Theije, J. J. Schermer, and W. J. P. van Enckevort, Effects of nitrogen impurities on the CVD growth of diamond: Step bunching in theory and experiment, Diam. Relat. Mater. 9, 1439 (2000).
[24] H. Yamada, A. Chayahara, and Y. Mokuno, Effects of intentionally introduced nitrogen and substrate temperature on growth of diamond bulk single crystals, Jpn. J. Appl. Phys. 55, 01AC07 (2015).
[25] H. Watanabe, T. Kitamura, S. Nakashima, and S. Shikata, Cathodoluminescence characterization of a nitrogen-doped homoepitaxial diamond thin film, J. Appl. Phys. 105, 093529 (2009).
[26] A. A. Khomich, O. S. Kudryavtsev, A. P. Bolshakov, V. A. Khomich, E. E. Ashkinazi, V. G. Ralchenko, I. I. Vlasov, and V. I. Konov, Use of optical spectroscopy methods to determine the solubility limit for nitrogen in diamond single crystals synthesized by chemical vapor deposition, J. Appl. Spectrosc. 82, 242 (2015).
[27] T. R. Eichhorn, C. A. McLellan, and A. C. Bleszynski Jayich, Optimizing the formation of depth-confined nitrogen vacancy center spin ensembles in diamond for quantum sensing, Phys. Rev. Mater. 3, 113802 (2019).
[28] A. Tallaire, O. Brinza, P. Huillery, T. Delord, C. Pellet-Mary, and R. Staacke, High NV density in a pink CVD diamond grown with N₂O addition, Carbon 170, 421 (2020).
[29] R. Samlenski, C. Haug, R. Brenn, C. Wild, R. Locher, and P. Koidl, Incorporation of nitrogen in chemical vapor deposition diamond, Appl. Phys. Lett. 67, 2798 (1995).
[30] M. Lesik, J. P. Tetienne, A. Tallaire, J. Achard, V. Mille, A. Gicquel, J. F. Roch, and V. Jacques, Perfect preferential orientation of nitrogen-vacancy defects in a synthetic diamond sample, Appl. Phys. Lett. 104, 113107 (2014).
[31] J. Michl, T. Teraji, S. Zaiser, I. Jakobi, G. Waldherr, F. Dolde, P. Neumann, M. W. Doherty, N. B. Manson, J. Isoya, and J. Wrachtrup, Perfect alignment and preferential orientation of nitrogen-vacancy centers during chemical vapor deposition diamond growth on (111) surfaces, Appl. Phys. Lett. 104, 102407 (2014).
[32] T. Fukui, Y. Doi, T. Miyazaki, Y. Miyamoto, H. Kato, T. Matsumoto, T. Makino, S. Yamasaki, R. Morimoto, N. Tokuda, M. Hatano, Y. Sakagawa, H. Morishita, T. Tashima, S. Miwa, Y. Suzuki, and N. Mizuochi, Perfect selective alignment of nitrogen-vacancy centers in diamond, Appl. Phys. Express 7, 055201 (2014).
[33] T. Miyazaki, Y. Miyamoto, T. Makino, H. Kato, S. Yamasaki, Y. Fukui, T. andDoi, N. Tokuda, M. Hatano, and N. Mizuochi, Atomistic mechanism of perfect alignment of nitrogen-vacancy centers in diamond, Appl. Phys. Lett. 105, 261601 (2014).
[34] H. Ozawa, K. Tahara, H. Ishiwata, M. Hatano, and T. Iwasaki, Formation of perfectly aligned nitrogen-vacancycenter ensembles in chemical-vapor-deposition-grown diamond (111), Appl. Phys. Express 10, 045501 (2017).
[35] C. Osterkamp, M. Mangold, J. Lang, P. Balasubramanian, T. Teraji, B. Naydenov, and F. Jelezko, Engineering preferentially-aligned nitrogen-vacancy centre ensembles in CVD grown diamond, Sci. Rep. 9, 1 (2019).
[36] P. Balasubramanian, C. Osterkamp, Y. Chen, X. Chen, T. Teraji, E. Wu, B. Naydenov, and R. L. Walsworth, dc magnetometry with engineered nitrogen-vacancy spin ensembles in diamond, Rev. Nano Lett. 19, 6681 (2019).
[37] I. Sakaguchi, M. Nishitani-Gamo, K. P. Loh, H. Hajime, and A. Toshihiro, Homoepitaxial growth and hydrogen incorporation on the chemical vapor deposited (111) diamond, J. Appl. Phys. 86, 1306 (1999).
[38] M. Kasu, T. Makimoto, W. Ebert, and E. Kohn, Formation of stacking faults containing microtwins in (111) chemical-vapor-deposited diamond homoepitaxial layers, Appl. Phys. Lett. 83, 3465 (2003).
[39] N. Tokuda, H. Umezawa, S. G. Ri, M. Ogura, K. Yamabe, H. Okushi, and S. Yamasaki, Atomically flat diamond (111) surface formation by homoepitaxial lateral growth, Diam. Relat. Mater. 17, 1051 (2008).
[40] L. K., Surface chemistry of diamond, in Novel Aspects of Diamond from Growth to Applications, edited by N. Yang (Springer International Publishing, Cham, 2015), pp. 53-83.
[41] S. Meynell, C. Mclellan, L. B. Hughes, W. Wang, T. E. Mates, K. Mukherjee, and A. C. B. Jayich, Engineering quantum-coherent defects: The role of substrate miscut in chemical vapor deposition diamond growth, Appl. Phys. Lett. 117, 194001 (2020).
[42] H. Kato, T. Makino, S. Yamasaki, and H. Okushi, N-type diamond growth by phosphorus doping on (001)-oriented surface, J. Phys. D 40, 6189 (2007).
[43] V. Mortet, A. Taylor, M. Davydova, J. Jiránek, L. Fekete, L. Klimša, D. Šimek, N. Lambert, S. Sedláková, J. Kopeček, and P. Hazdra, Effect of substrate crystalline orientation on boron-doped homoepitaxial diamond growth, Diam. Relat. Mater. 122, 108887 (2022).
[44] Y. Nakano, X. Zhang, K. Kobayashi, T. Matsumoto, T. Inokuma, S. Yamasaki, C. E. Nebel, and N. Tokuda, Impact of nitrogen doping on homoepitaxial diamond (111) growth, Diam. Relat. Mater. 125, 108997 (2022).
[45] A. Tallaire, M. Lesik, V. Jacques, S. Pezzagna, V. Mille, O. Brinza, J. Meijer, B. Abel, J. F. Roch, A. Gicquel, and J. Achard, Temperature dependent creation of nitrogenvacancy centers in single crystal CVD diamond layers, Diam. Relat. Mater. 51, 55 (2015).
[46] H. Ishiwata, M. Nakajima, K. Tahara, H. Ozawa, T. Iwasaki, and M. Hatano, Perfectly aligned shallow ensemble nitro-gen-vacancy centers in (111) diamond, Appl. Phys. Lett. 111, 043103 (2017).
[47] T. Wolf, P. Neumann, K. Nakamura, H. Sumiya, T. Ohshima, J. Isoya, and J. Wrachtrup, Subpicotesla diamond magnetometry, Phys. Rev. X 5, 041001 (2015).
[48] C. Osterkamp, P. Balasubramanian, G. Wolff, T. Teraji, M. Nesladek, and F. Jelezko, Benchmark for synthesized diamond sensors based on isotopically engineered nitro-gen-vacancy spin ensembles for magnetometry applications, Adv. Quantum Technol. 3, 2000074 (2020).
[49] M. E. Ziffer et al., Quantum noise spectroscopy of criticality in an atomically thin magnet, arXiv: 2407.05614.
[50] M. A. Perlin, C. Qu, and A. M. Rey, Spin squeezing with short-range spin-exchange interactions, Phys. Rev. Lett. 125, 223401 (2020).
[51] G. Bornet, G. Emperauger, C. Chen, B. Ye, M. Block, M. Bintz, J. A. Boyd, D. Barredo, T. Comparin, F. Mezzacapo, T. Roscilde, T. Lahaye, N. Y. Yao, and A. Browaeys, Scalable spin squeezing in a dipolar Rydberg atom array, Nature (London) 621, 728 (2023).
[52] A. Dréau, M. Lesik, L. Rondin, P. Spinicelli, O. Arcizet, J.-F. Roch, and V. Jacques, Avoiding power broadening in optically detected magnetic resonance of single NV defects for enhanced dc magnetic field sensitivity, Phys. Rev. B 84, 195204 (2011).
[53] J. P. Chou, A. Retzker, and A. Gali, Nitrogen-terminated diamond (111) surface for room-temperature quantum sensing and simulation, Nano Lett. 17, 2294 (2017).
[54] J. P. Chou and A. Gali, Nitrogen-vacancy diamond sensor: Novel diamond surfaces from ab initio simulations, MRS Commun. 7, 551 (2017).
[55] S. M. Parks, R. R. Grotea, D. A. Hopper, and L. C. Bassett, Fabrication of (111)-faced single-crystal diamond plates
   by laser nucleated cleaving, Diam. Relat. Mater. 84, 20 (2018).
[56] C. A. Mclellan, B. A. Myers, S. Kraemer, K. Ohno, D. D. Awschalom, and A. C. B. Jayich, Patterned formation of highly coherent nitrogen-vacancy centers using a focused electron irradiation technique, Nano Lett. 16, 2450 (2016).
[57] S. Meynell, Dimensionality in dipolar quantum systems, Ph.D. thesis, University of California Santa Barbara, 2024.
[58] G. Cao, J. Schermer, W. van Enckevort, L. Elst, and W. A. L. M. L. J. Giling, Growth of 100 textured diamond films by the addition of nitrogen, J. Appl. Phys. 79, 1357 (1996).
[59] J. F. Barry, J. M. Schloss, E. Bauch, M. J. Turner, C. A. Hart, L. M. Pham, and R. L. Walsworth, Sensitivity optimization for NV-diamond magnetometry, Rev. Mod. Phys. 92, 015004 (2020).
[60] W. Wu, XY8-ODMR theory (to be published).

Further information on one or more embodiments disclosed herein can be found in “A Strongly Interacting, Two-Dimensional, Dipolar Spin Ensemble in (111)-Oriented Diamond” by Lillian B. Hughes, Simon A. Meynell, Shreyas Parthasarathy, Lingjie Chen, Zhiran Zhang, Ania C. Bleszynski Jayich, Weijie Wu, Zilin Wang, Emily J. Davis, Norman Y. Yao, and Kunal Mukherjee PHYSICAL REVIEW X 15, 021035 (2025) and supplementary information.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A composition of matter, comprising:
a diamond layer having a (111) orientation or miscut thereof, wherein the diamond layer comprises a doped layer comprising a two dimensional ensemble of nitrogen vacancy centers.

2. The composition of matter of claim 1, wherein the two dimensional ensemble is characterized by all spacings of nearest neighbor ones of each of the centers in an area of a two dimensional plane of the doped layer being larger than a thickness of the doped layer at any point in the area.

3. The composition of matter of claim 1, wherein the two dimensional ensemble is characterized by the spins of the centers generating a non-zero dipolar induced mean field distribution.

4. The composition of matter of claim 3 wherein the dipolar induced-induced mean field distribution is characterized by an asymmetric lineshape measuring response as a function of RF frequency.

5. The composition of matter of claim 4 wherein the asymmetric lineshape that measured in the presence of a dynamical decoupling pump wherein the asymmetry is on one side of the response when the NV centers are initialized in an mₛ=0 state and on the other side of the lineshape when the NV centers are initialized in the mₛ=+1 or mₛ=−1 states.

6. The composition of matter of claim 5 wherein the lineshape is asymmetric about a zero detuning of a frequency of a probe with respect to the frequency of the pump when the probe is measuring the lineshape.

7. The composition of matter of claim 3, wherein the mean field distribution is characterized by an asymmetric spectrum with a sign flip when the spins are initialized in an opposite state, as measured by a pump probe measurement when the ensemble is dynamically decoupled from sources of disorder in the surrounding lattice.

8. The composition of matter of claim 1, wherein the dopant layer comprises a dopant density of nitrogen atoms up to a value that maintains a condition of two-dimensionality.

9. The composition of matter of claim 1, wherein the dopant layer is two dimensional as characterized by the stretch exponent n of a coherence decay e^{-(t/T}^{₂}⁾^{ⁿ} measurement of n=⅔ where T₂ is the coherence time measured during dynamical decoupling.

10. A magnetic field sensor comprising the composition of matter of claim 1.

11. A sensor configured for entanglement-enhanced metrology or quantum simulation comprising the composition of matter of claim 1.

12. A method of making a composition of matter, comprising:
growing a diamond epilayer on a 111 orientation or miscut surface of a (111) diamond substrate; and
delta-doping the epilayer with nitrogen dopants in a dopant layer; wherein:
the miscut (if any) and a dopant concentration of nitrogen dopants are selected so that:
the nitrogen dopants convert to a two dimensional ensemble of nitrogen vacancy centers in the dopant layer.

13. The method of claim 12, wherein the miscut (if any) and dopant concentration are selected so that:
all spacings of nearest neighbor ones of each of the centers in an area of a two dimensional plane of the dopant layer are larger than a thickness of the dopant layer at each point in the area, and/or
the spins of the centers generate a non-zero dipolar induced mean field distribution.

14. The method of claim 12, further comprising:
in a PECVD reactor, growing the diamond epilayer on a surface of a diamond substrate having a 111 orientation or miscut thereof, under conditions to form a ¹²C isotopically purified epilayer of diamond; and
during a nitrogen delta-doping period of growth forming the dopant layer, introducing a dopant gas flow into the PECVD reactor together with the precursors flow.

15. The method of claim 14 wherein the surface normal of the surface is in a range of 0-3 degrees with respect to a surface normal of the 111 plane and the delta doping introduces a dopant density of nitrogen atoms in a range of 300-1.9×10⁴ ppm nm.

16. A method of testing or operating a device, comprising:
irradiating a sample comprising nitrogen vacancy (NV) centers in a surrounding lattice with a pump sequence of electromagnetic radiation to resonantly drive the NV centers into an initial spin state and decouple the NV ensemble from sources of disorder in the surrounding lattice;
simultaneously with the pump sequence, irradiating the sample with a probe RF pi pulse of varying frequency, wherein frequencies of the probe resonant with a transition between an mₛ=0 to an mₛ=+/1 state may flip the initial spin state between the mₛ=0 and the mₛ=+/1 state;
exciting the sample with a readout beam generating fluorescence from the sample to obtain a disorder-suppressed spectrum representing a spin population in the sample;
observing whether there is an asymmetry in the lineshape of the spectrum whose sign flips when the initial spin state is flipped and
associating the asymmetry with non-zero dipolar interactions of the NV ensemble.

17. The method of claim 16 testing or operating the device comprising the composition of matter of claim 1.

18. The method of claim 16, wherein the pump sequence is a dynamical decoupling sequence comprising XY8-ODMR or DROID.
